(19) United States
(12) Patent Application Publication
(10) Pub. No.: US 2025/0316666 A1
(43) Pub. Date: Oct. 9, 2025

(54) HYBRID-BONDED INTERPOSER FOR HIGH-DENSITY INTERFACE CONNECTIONS IN SEMCONDUCTOR DEVICES

(71) Applicant: Marvell Asia Pte Ltd, Singapore (SG)

(72) Inventors: Aatreya Chakravarti, Winooski, VT (US); Carlos Macian Ruiz, Los Gatos, CA (US); Mark William Kuemerle, Essex Junction, VT (US); Wolfgang Sauter, Starksboro, VT (US); John Edward Gregory, Jr., Dummerston, VT (US); Eva Shah Holmes, Wappingers Falls, NY (US); Samer Akiki, Redwood City, CA (US); Kazin Simon Blacklow, Burlington, VT (US); Ting Zheng, San Jose, CA (US); Carl E Benes, Waterbury, VT (US)

(21) Appl. No.: 19/169,429

(22) Filed: Apr. 3, 2025

Related U.S. Application Data
(60) Provisional application No. 63/574,674, filed on Apr. 4, 2024.

(51) Int. Cl. H01L 25/18; H01L 23/00; H01L 23/14; H01L 23/538; H03K 19/0175; H10D 80/30

(52) U.S. Cl. CPC H01L 25/18; H01L 23/14; H01L 23/5385; H01L 23/5386; H01L 24/08; H01L 24/80; H03K 19/017509; H10D 80/30; H01L 2224/08225; H01L 2224/80895; H01L 2224/80896; H01L 2924/1433

(57) ABSTRACT

A semiconductor package includes a first chip including a first die-to-die interface with a first plurality of flip-flops, and a second chip including a second die-to-die interface with a second plurality of flip-flops, and an interposer configured to provide paths for data to flow between the first die-to-die interface and the second die-to-die interface. The interposer is mechanically coupled to the first chip and to the second chip by a first hybrid bond and a second hybrid bond, respectively, the interposer including a first plurality of interposer vias coupled to the first plurality of flip-flops across the first hybrid bond, a second plurality of interposer vias coupled to the second plurality of flip-flops across the second hybrid bond, and a plurality of lateral metal traces coupling respective vias among the first plurality of interposer vias to respective vias among the second plurality of interposer vias to provide the paths.

### CROSS REFERENCE TO RELATED APPLICATION

This disclosure claims the benefit of copending, commonly-assigned U.S. Provisional Patent Application No. 63/574,674, filed Apr. 4, 2024, which is hereby incorporated by reference herein in its entirety.

### FIELD OF USE

This disclosure relates to interfaces in semiconductor devices. More particularly, this disclosure relates to interfaces over a hybrid-bonded interposer for high-density interface connections in semiconductor devices.

### BACKGROUND

The background description provided herein is for the purpose of generally presenting the context of the disclosure. Work of the inventors hereof, to the extent the work is described in this background section, as well as aspects of the description that may not otherwise qualify as prior art at the time of filing, are neither expressly nor impliedly admitted to be prior art against the subject matter of the present disclosure.

Semiconductor devices may include multi-chip modules (MCMs) for various processing applications. Within an MCM, separate dies or chiplets may share data over electrical connections coupling respective die-to-die (D2D) interfaces of the separate dies. These electrical connections may limit bandwidth, latency, and/or other performance specifications related to processing by the MCM.

### SUMMARY

In accordance with implementations of the subject matter of this disclosure, a semiconductor package for increasing density of die-to-die interface connections includes a first chip including a first die-to-die interface, the first die-to-die interface including a first plurality of flip-flops configured to send and receive data, and a second chip including a second die-to-die interface, the second die-to-die interface including a second plurality of flip-flops configured to send and receive data, and an interposer configured to provide a plurality of paths for data to flow between the first die-to-die interface and the second die-to-die interface, the interposer being mechanically coupled to the first chip and to the second chip by a first hybrid bond and a second hybrid bond, respectively, the interposer including a first plurality of interposer vias being electrically coupled to the first plurality of flip-flops across the first hybrid bond, a second plurality of interposer vias being electrically coupled to the second plurality of flip-flops across the second hybrid bond, and a plurality of lateral metal traces electrically coupling respective vias among the first plurality of interposer vias to respective vias among the second plurality of interposer vias to provide the plurality of paths.

In a first implementation of such a package, the interposer may be configured to provide the plurality of paths for parallel data to flow at a target bandwidth between the first die-to-die interface and the second die-to-die interface.

In a first aspect of that first implementation, the first chip and the second chip may be configured to send and receive the parallel data at the target bandwidth based on respective densities of the first plurality of interposer vias and of the second plurality of interposer vias.

In a second implementation of such a package, the first die-to-die interface may further include a plurality of transmitters, respective flip-flops among the first plurality of flip-flops are configured to provide respective portions of the data as parallel data, and respective transmitters among the plurality of transmitters are configured to drive the respective portions of the data through the interposer. In a first aspect of that second implementation, the first die-to-die interface may further include a plurality of buffers, respective buffers among the plurality of buffers being configured to electrically isolate a respective lateral metal trace among the plurality of lateral metal traces.

In a second aspect of that second implementation, the second die-to-die interface may further include a plurality of receivers, respective receivers among the plurality of receivers may be configured to provide the respective portions of the data to the second plurality of flip-flops, and respective flip-flops among the second plurality of flip-flops may be configured to receive the respective portions of the data.

In a third implementation of such a package, the interposer may include a plurality of buffers configured to drive the data through the plurality of paths, each buffer of the plurality of buffers being coupled to a respective path of the plurality of paths.

In a fourth implementation of such a package, the first die-to-die interface may be at least partially offset from an edge of the first chip by a distance that is greater than a maximum distance specified by Joint Electron Device Engineering Council standards.

In a fifth implementation of such a package, the interposer may include at least two silicon substrates stitched together, such that the interposer is larger than a maximum reticle size associated with a fabrication process used to manufacture any of the at least two silicon substrates.

In a sixth implementation of such a package, the interposer may include at least two silicon substrates stitched together, and each lateral metal trace among the plurality of lateral metal traces spans at least two among the at least two silicon substrates stitched together.

In a seventh implementation of such a package, the first chip may be an application specific integrated circuit, the second chip may be a chiplet among a plurality of chiplets configured to support operation of the application specific integrated circuit, and the interposer may be hybrid-bonded to each chiplet among the plurality of chiplets, electrically coupled to each chiplet among the plurality of chiplets by a respective plurality of interposer vias and by a respective plurality of lateral metal traces, and further configured to provide additional pluralities of paths for data to flow between the first die-to-die interface and any die-to-die interface of a respective chiplet among the plurality of chiplets.

In accordance with implementations of the subject matter of this disclosure, a method for sharing data between die-to-die interface connections of a semiconductor package includes forming a first hybrid bond between an interposer and a first chip, the interposer having a first plurality of interposer vias and a second plurality of interposer vias, the first chip having a first die-to-die interface that is electrically coupled to the first plurality of interposer vias across a region of the first hybrid bond, forming a second hybrid bond between the interposer and a second chip, the second chip having a second die-to-die interface that is electrically coupled to the second plurality of interposer vias across a region of the second hybrid bond, and providing a plurality of paths for data to flow between the first die-to-die interface and the second die-to-die interface, through the interposer, the plurality of paths including a plurality of lateral metal traces electrically coupling respective vias among the first plurality of interposer vias to respective vias among the second plurality of interposer vias.

In a first implementation of such a method, providing the plurality of paths for data to flow may include providing the plurality of paths for parallel data to flow at a target bandwidth between the first die-to-die interface and the second die-to-die interface.

A first aspect of that first implementation may further include configuring the first chip and the second chip to send and receive the parallel data at the target bandwidth based on respective densities of the first plurality of interposer vias and of the second plurality of interposer vias.

In a second implementation of such a method, the first die-to-die interface may further include a plurality of transmitters, and the method may further include providing respective portions of the parallel data using respective flip-flops among the first plurality of flip-flops, and driving the respective portions of the parallel data through the interposer using respective transmitters among the plurality of transmitters.

In a first aspect of that second implementation, the first die-to-die interface may further include a plurality of buffers, and the method may further include electrically isolating, using the plurality of buffers, respective lateral metal traces among the plurality of lateral metal traces.

In a second aspect of that second implementation, the second die-to-die interface may include a plurality of receivers, and the method may further include providing, using respective receivers among the plurality of receivers, the respective portions of the parallel data to the second plurality of flip-flops, and receiving, using respective flip-flops among the second plurality of flip-flops, the respective portions of the parallel data.

A third implementation of such a method may further include driving, using a plurality of buffers of the interposer, the data through the plurality of paths, each buffer of the plurality of buffers being coupled to a respective path of the plurality of paths.

In a fourth implementation of such a method, the first die-to-die interface may be at least partially offset from an edge of the first chip by a distance that is greater than a maximum distance specified by Joint Electron Device Engineering Council standards.

A fifth implementation of such a method may further include stitching together at least two silicon substrates to form the interposer, such that the interposer is larger than a maximum reticle size associated with a fabrication process used to manufacture any of the at least two silicon substrates.

A sixth implementation of such a method may further include stitching together at least two silicon substrates to form the interposer, and configuring each lateral metal trace among the plurality of lateral metal trace to span at least two silicon substrates among the at least two silicon substrates stitched together.

In a seventh implementation of such a method, the first chip may be an application specific integrated circuit and the second chip may be a chiplet among a plurality of chiplets configured to support operation of the application specific integrated circuit, and the method may further include forming a plurality of additional hybrid bonds between the interposer and a respective chiplet among the plurality of chiplets, electrically coupling the interposer to each chiplet among the plurality of chiplets by a respective plurality of interposer vias and by a respective plurality of lateral metal traces, and providing, using the interposer, additional pluralities of paths for data to flow between the first die-to-die interface and any die-to-die interface of a respective chiplet among the plurality of chiplets.

In accordance with implementations of the subject matter of this disclosure, a method of manufacturing a semiconductor package includes forming a first hybrid bond between an interposer and a first chip, the interposer having a first plurality of interposer vias and a second plurality of interposer vias, the first chip having a first die-to-die interface that is configured to be electrically coupled to the first plurality of interposer vias across a region of the first hybrid bond, forming a second hybrid bond between the interposer and a second chip, the second chip having a second die-to-die interface that is configured to be electrically coupled to the second plurality of interposer vias across a region of the second hybrid bond, and configuring the interposer to provide a plurality of paths for data to flow between the first die-to-die interface and the second die-to-die interface, through the interposer, the plurality of paths comprising a plurality of lateral metal traces electrically coupling respective vias among the first plurality of interposer vias to respective vias among the second plurality of interposer vias.

### BRIEF DESCRIPTION OF THE DRAWINGS

Further features of the disclosure, its nature and various advantages, will be apparent upon consideration of the following detailed description, taken in conjunction with the accompanying drawings, in which like reference characters refer to like parts throughout, and in which:

FIG. 1 is an illustrative block diagram of a semiconductor package including a hybrid-bonded interposer to provide high-density interface connection between respective dies of the semiconductor device, in accordance with implementations of the subject matter of this disclosure;

FIG. 2 is an illustrative diagram of a data flow path between respective chips connected by a hybrid-bonded interposer, in accordance with implementations of the subject matter of this disclosure;

FIG. 3 is an exploded view of a portion of a semiconductor package including multiple dies hybrid-bonded to a stitched interposer, as well as a data flow path through the interposer, in accordance with implementations of the subject matter of this disclosure;

FIG. 4 is a flow diagram of an illustrative implementation of a method for sharing data between die-to-die interface connections of a semiconductor package, in accordance with the subject matter of this disclosure; and

FIG. 5 is a flow diagram of an illustrative implementation of a method for manufacturing a semiconductor package, in accordance with the subject matter of this disclosure.

### DETAILED DESCRIPTION

Multi-chip module (MCM) semiconductor devices may provide capabilities beyond that which a single semiconductor chip can achieve, because the maximum size of a single semiconductor chip may be limited, for example, by the maximum reticle size in the photolithographic process used to fabricate the chip. In an MCM semiconductor device (which may simply be referred to as an MCM), data may be shared between respective chips and/or chiplets of the device, e.g., using an interposer or any other suitable semiconductor device component. Computing capabilities of the MCM may depend on the throughput and latency associated with this data sharing.

In an MCM, shared data could be serialized at a first chip, coupled to an interposer through a first set of microbump connections, routed through the interposer, coupled to a second chip of the MCM through a second set of microbump connections, and deserialized at the second chip of the MCM. However, existing fabrication processes may be limited with respect to how small the microbumps can be, or with respect to how much of the area of a chip can be covered with microbumps. Thus, the density of microbump connections may be limited, thereby limiting a number of parallel communication channels between the first and second chips. An undesirable amount of power may also be required to drive signals through microbumps. In addition, the use of serialization and deserialization may also consume an undesirable amount of power, may give rise to an undesirable amount of latency when transferring data within the MCM, and may constrain the number of channels available for transferring the data (and, correspondingly, a data transfer bandwidth), because, e.g., Joint Electron Device Engineering Council (JEDEC) standards constrain a D2D interface with serialization and deserialization circuitry to be disposed on limited “beachfront” area of a chip.

In another MCM, data may be vertically shared between two chips that each have active silicon devices and that are stacked and hybrid-bonded to each other. However, an MCM including stacked chips may have limited heat dissipation capabilities (e.g., because of the physical proximity of the two stacked, heat-generating chips) and may have a less robust power delivery network (e.g., because a power delivery network shared between the stacked chips would have to traverse the hybrid-bonded interface, making the network more sensitive to noise, resistive drops, and parasitic effects).

In accordance with implementations of the subject matter of this disclosure, an MCM includes at least two chips, both of which are hybrid-bonded to an interposer configured to route data between the two chips. Because the two chips are hybrid-bonded to the interposer, data can be shared to and from the chips through multiple parallel paths, with each parallel path including a pair of interposer vias connected by a lateral metal trace of the interposer, thereby increasing the density of connections as compared, e.g., to an implementation using microbumps (at least in part because the minimum size of an interposer via is smaller than the minimum size of an interposer microbump). Based on the increased density of connections, the two chips that are connected by a hybrid-bonded interposer can achieve a target bandwidth using multiple instances of slower, simple flip-flop interfaces, rather than more complex serializer/deserializer interfaces, to, e.g., transfer a comparable amount of data with reduced latency and/or reduced power consumption.

In some implementations, each respective narrow data flow path (e.g., including a transmitting flip-flop, a transmitting-side interposer via, a connecting lateral metal trace, a receiving-side interposer via, and a receiving flip-flop) of MCMs provided in this disclosure may contribute less data transfer bandwidth than a wide data path routing serialized data through a pair of microbumps. However, because the use of vias permits a greater path density than does the use of microbumps (at least in part because vias are smaller than microbumps), the overall data transfer bandwidth may be increased, or may otherwise be made comparable with less power consumption and/or latency.

In one implementation, respective data flow paths of the MCM transmit serialized data (e.g., through a high density of data flow paths including interposer vias) for extra-high-bandwidth data transfer.

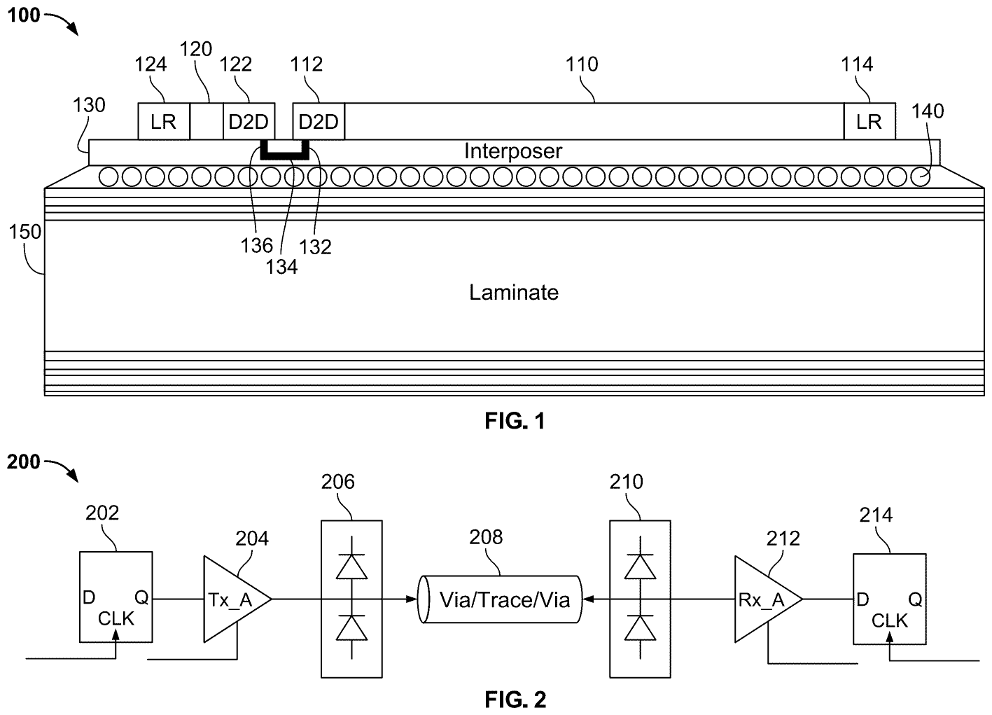

The subject matter of this disclosure is further described below with reference to FIGS. 1-5.

FIG. 1 is an illustrative block diagram of an MCM semiconductor package 100 including a hybrid-bonded interposer 130 to provide high-density interface connections between respective dies of the semiconductor package, in accordance with implementations of the subject matter of this disclosure. MCM semiconductor package 100 includes first chip 110 and second chip 120, each of which is mechanically and electrically coupled to interposer 130 by a respective hybrid bond. Those respective hybrid bonds may be formed separately, or may be simultaneously formed within a single fabrication step.

First chip 110 includes first die-to-die (D2D) interface 112, which is electrically coupled to interposer 130 through a first set of interposer vias 132, which are represented by a single line for ease of illustration. Second chip 120 includes second D2D interface 122, which is electrically coupled to interposer 130 through a second set of interposer vias 136, which are also represented by a single line for ease of illustration. As further described below, although first D2D interface 112 and second D2D interface 122 are shown in FIG. 1 as being disposed at respective edges of first chip 110 and second chip 120, either of those D2D interfaces may be offset from either of the corresponding chip edges when the D2Ds include flip-flop interfaces, rather than serializer/deserializer circuitry. With respect to the hybrid bond interface between interposer 130 and the aforementioned first and second chips, the first set of interposer vias 132 electrically couples to a first portion of the interface and the second set of interposer vias 136 electrically couples to a second portion of the interface. For example, bond pads or other electrical contacts on the first chip 110 and on the second chip 120 may span the interface and electrically couple to the corresponding sets of interposer vias.

While hybrid-bonding two integrated circuit chips in a stacked arrangement may introduce challenges associated with heat dissipation and/or power delivery, as mentioned above, those challenges are mitigated (or may be made irrelevant) when hybrid-bonding a single integrated circuit chip and an interposer. An interposer itself does not generate a significant amount of heat, meaning that an integrated circuit chip hybrid-bonded atop an interposer does not sit atop a heat source, as would an integrated circuit chip hybrid-bonded atop another integrated circuit chip as is done in conventional hybrid-bonding scenarios. Similarly, an interposer does not require a significant amount of power, meaning that the interposer does not give rise to noise or power supply fluctuations, as could occur when an integrated circuit chip that is hybrid-bonded to another integrated circuit chip.

First chip 110 also includes long reach (LR) interface 114, and second chip 120 also includes LR interface 124. Each of these LR interfaces may communicatively couple the corresponding chip to additional circuitry, e.g., to share data between either of the two chips and off-chip circuitry (e.g., that may be external to the MCM or to laminate 150).

Interposer 130 includes a set of lateral metal traces 134, which are represented by a single line for ease of illustration. Each lateral metal trace may include a first end that is electrically coupled to a respective via among the first set of vias 132, and a second end that is electrically coupled to a respective via among the second set of vias 136. A continuous electrical path including a via among a first set of vias, a lateral metal trace, and a via among a second set of vias, may be referred to herein as a “narrow data path.” For example, a set of narrow data paths may couple respective channels of D2D interface 112 to corresponding channels of D2D interface 122.

Respective traces of the set of lateral metal traces may be disposed parallel to each other in any suitable arrangement (e.g., into or out of the plane shown in FIG. 1, and/or above or below each other). In one implementation, with respect to the distances traversed by each set of interposer vias 132 and 136 (e.g., which is through a thickness dimension of interposer 130, and which may be regarded as vertical distances), the set of lateral metal traces 134 are arranged perpendicularly. Such a perpendicular arrangement is depicted by the line representing the set of lateral metal traces 134 being drawn perpendicular to the respective lines representing the first set of interposer vias 132 and the second set of interposer vias 136.

Interposer 130 may be entirely passive silicon, including only metal connections, or interposer 130 may also include active electronic devices (e.g., silicon-based devices) formed in the interposer 130. In particular, interposer 130 may include one or more buffers configured to drive data that is routed through interposer 130. For example, each buffer may be configured to drive data through multiple narrow data paths, there may be one or more buffers for each narrow data path, or there may be any other suitable arrangement of buffers to drive data through narrow data paths.

When using D2D interfaces incorporating flip-flops, e.g., in place of serialization/deserialization circuitry, a location of the D2D interface is not constrained (e.g., by Joint Electron Device Engineering Council standards) to be disposed on “beachfront” area of the chip, or on any portion of the edge of the chip. Thus, in one implementation, at least one of the first D2D interface 112 or the second D2D interface 122 is offset from an edge of the corresponding chip. When a D2D interface is offset from an edge of the corresponding chip, it may be offset by a distance that is greater than a maximum distance specified by JEDEC standards. For example, D2D interface 112 may be disposed in the middle of first chip 110, or D2D interface 122 may be disposed next to LR 124. This offset increases the lateral distance spanned by lateral metal traces 134. Accordingly, the aforementioned interposer buffers are implemented to drive the shared data across the increased lateral distance. That is, narrow data paths may be lengthened due to at least one D2D interface being offset from the edge of a chip, and at least one buffer may be configured to drive data through the lengthened paths.

As mentioned, and as further described below, the semiconductor package 100 is configured for data sharing between first chip 110 and second chip 120 through interposer 130. Because interposer 130 is hybrid-bonded to both of the first chip 110 and the second chip 120, this data sharing occurs across respective sets of interposer vias 132 and 136. The hybrid-bonding permits using vias, instead of microbumps, to share data between each chip and the interposer. The use of vias, instead of microbumps, provides an increased density of electrical connections. Based on this increased density of electrical connections, first D2D interface 112 and second D2D interface 122 may each incorporate flip-flops, rather than serializer/deserializer circuitry, to send and receive data. By using flip-fops, power consumption and latency associated with data sharing may be reduced. Moreover, the increased density provides an increased number of parallel data paths (e.g., through interposer 130), and these parallel data paths permit data sharing at a target bandwidth, e.g., that might otherwise require serialization and deserialization.

However, in one implementation, each of first D2D interface 112 and second D2D interface 122 may include serializer/deserializer circuitry coupled to interposer vias 132 or 136, respectively. Accordingly, serialized data may be shared across the increased number of data paths to provide for extra-high-bandwidth data transfer.

Interposer 130 is mounted on laminate 150, which may be a printed circuit board or any other suitable substrate. A set of microbumps 140 electrically couples interposer 130 to laminate 150. Through the microbumps 140, data from either (or both) of first chip 110 or second chip 120 can be provided to other chips. Moreover, a power delivery network, external clock, any other supporting circuitry, or any combination thereof, may be coupled to first chip 110 and second chip 120 through the microbumps 140.

FIG. 2 is an illustrative diagram of a data flow path 200 between respective chips connected by a hybrid-bonded interposer, in accordance with implementations of the subject matter of this disclosure. For example, data flow path 200 may communicatively couple first chip 110 to second chip 120. Data flow path 200 shows how, in any transmitting chip, data is provided by flip-flop 202 and driven by transmitter 204 through buffer 206. On the other side of the buffer 206, data flows through the interposer, namely through narrow data path 208, which includes a first interposer via, a lateral a lateral metal trace, and a second interposer via. Having been transferred through narrow data path 208, the data is received by any receiving chip based on flowing through buffer 210, receiver 212, and flip-flop 214.

Given a set of data flow paths 200, each buffer 206 and each buffer 210 may electrically isolate each respective data flow path 200 from other data flow paths 200. For example, those buffers may isolate respective narrow data paths, or respective portions thereof, from each other.

Each of D2D interface 112 and D2D interface 122 may include multiple flip-flops 202, transmit amplifiers 204, and buffers 206 (e.g., the number of the multiple flip-flops corresponding to the number of narrow data paths). Moreover, each of D2D interface 112 and D2D interface 122 may include multiple buffers 210, receive amplifiers 212, and flip-flops 214 (e.g., the number of the multiple flip-flops corresponding to the number of narrow data paths). That is, each of D2D interface 112 and D2D interface 122 may be a bidirectional interface (e.g., corresponding to bidirectional interface 302 or bidirectional interface 310) that is configured to send or receive data.

As shown in FIG. 2, first chip 110 may be the transmitting chip (e.g., including flip-flop 202, transmit amplifier 204, and buffer 206) or the receiving chip (e.g., including buffer 210, receive amplifier 212, and flip-flop 214); the same is true of second chip 120. Narrow data path 208 may be disposed in interposer 130. For example, the transmitting-side interposer via of narrow data path 208 may be an interposer via among the set of interposer vias 132, and the receiving-side interposer via of narrow data path 208 may be an interposer via among the set of interposer vias 136, or vice versa.

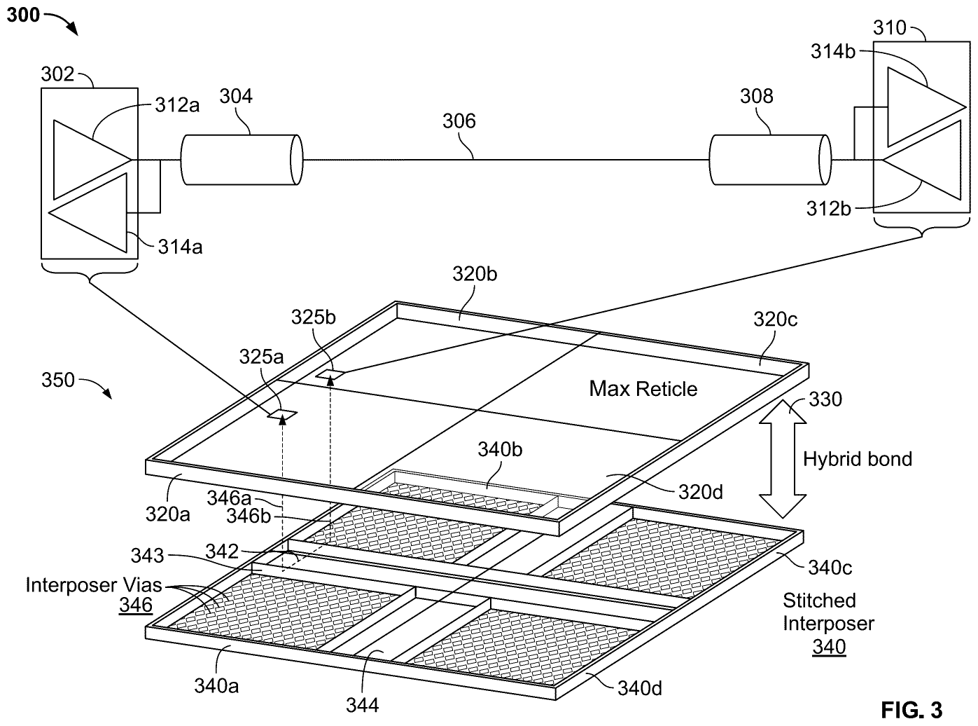

FIG. 3 is an exploded depiction of multiple dies hybrid-bonded to a stitched interposer, along with a depiction of a corresponding data flow path through the interposer, in accordance with implementations of the subject matter of this disclosure. As used herein, a stitched interposer refers to an interposer that is made up of multiple discrete silicon substrates having edges that are stitched together using any suitable mechanical coupling technique. Because it is made up of multiple silicon substrates, the size of a stitched interposer can exceed a maximum reticle size associated with a fabrication process used to fabricate either (or both) of the at least two silicon substrates.

As shown in FIG. 3, data flow path 300 may correspond to data flow path 200, and semiconductor package 350 may correspond to semiconductor package 100, as further described below.

Data flow path 300 includes a first bidirectional interface 302 (e.g., corresponding to interface 325a) having transmitter block 312a to send data through data flow path 300 and receiver block 314a to receive data from data flow path 300. First bidirectional interface 302 is electrically coupled to interposer via 304 (e.g., an interposer via among the set of interposer vias 132 or 136). Interposer via 304 is electrically coupled to lateral metal trace 306 (e.g., a lateral metal trace among the set of lateral metal traces 134). Lateral metal trace 306 is electrically coupled to interposer via 308 (e.g., an interposer via among the set of interposer vias 132 or 136). Lateral metal trace 306 may be configured to span stitched region 343 and/or stitched region 344 to permit data flow path 300 to span at least two respective silicon substrates of stitched interposer 340. Interposer via 308 is electrically coupled to a second bidirectional interface 310 (e.g., corresponding to interface 325b) having transmitter block 312b to send data through data flow path 300 and receiver block 314b to receive data from data flow path 300.

In some implementations, semiconductor package 100 or semiconductor package 350 includes multiple data flow paths 300 arranged in parallel. These multiple data flow paths 300 may start at respective interface channels of a first D2D interface and may end at respective interface channels of a second D2D interface. Accordingly, parallel data can be shared between the respective D2D interfaces over the set of parallel data flow paths 300 and the respective interface channels.

As mentioned, respective interposer vias 304 and interposer via 308 may be arrayed with a higher density than can be achieved using microbumps. Because of this higher density, data flow path 300 may include flip-flops at interfaces 302 and 310, rather than serializer/deserializer circuitry, without sacrificing the overall bandwidth (e.g., as might otherwise occur when transmitting data that is not serialized). Moreover, because of sending and receiving data using flip-flops, data flow path 300 can operate with less power and/or less latency than a similar data flow path relying on serializer/deserializer circuitry.

Even so, an implementation could retain serializer/deserializer circuitry at interfaces 302 and 310, in which case extra-high-bandwidth transmission (e.g., based on serializing and transmitting data through each of the high-density parallel paths) can be achieved.

Semiconductor package 350 extends the architecture of semiconductor package 100 across a stitched interposer 340, and optionally adds additional chips beyond the first chip 110 and the second chip 120. The stitched interposer 340 can be any suitable size, including being larger than a maximum reticle size associated with a fabrication process of any of the respective silicon substrates of the stitched interposer 340. As shown in FIG. 3, stitched interposer 340 combines four respective substrates, each corresponding a maximum reticle size, making stitched interposer 340 quadruple the maximum reticle size. That is, an active silicon layer includes silicon areas 320a-d, which includes at least two chips (each of the at least two chips occupying any suitable portion of the corresponding active silicon area), and a stitched interposer 340 includes interposer substrates 340a-d. A respective silicon area may be wholly or partially occupied by one or more silicon chips. Each interposer substrate may be independently fabricated and then stitched to the neighboring interposer substrate using any suitable mechanical coupling technique. Stitched regions 343 and 344 are shown to depict stitched interfaces of the stitched interposer 340. Lateral metal traces, as shown by the dashed line depicting a lateral metal trace 342, may traverse the stitched regions. For example, two respective silicon substrates may include respective portions of a lateral metal trace 306, these respective portions may be electrically connected to each other through a stitching region 343 or 344. That is, when stitching together respective silicon substrates of a stitched interposer, the stitching process may include forming interfacial electrical connections (e.g., at respective edges of respective silicon substrates) between respective lateral metal traces of the respective silicon substrates, such that the resulting narrow data paths may traverse at least two of the respective silicon substrates. With respective portions of a lateral metal trace 306 being electrically coupled together due to a stitching process, data may be driven across the entire lateral metal trace 306 (and, thus, across at least one stitching region 343 or 344) using techniques similar to those described at least in connection with FIGS. 1-2.

Interposer substrates 340a-d are attached to silicon areas 320a-d through respective hybrid bonds 330. That is, each respective interposer substrate is hybrid-bonded to one or more silicon chips occupying the corresponding silicon area (before or after stitching). The interposer may be a passive device, in which case each single hybrid-bond couples active silicon to passive silicon. Alternatively, the stitched interposer 340 may include one or more buffers (e.g., where each of multiple narrow data paths is supported by one or more respective buffer) configured to drive data through the stitched interposer 340. Whether stitched interposer 340 is a passive device or an active device (e.g., with buffers), it is noted that data may flow between any two or more of respective silicon substrates 340a-d across corresponding stitched interfaces.

Each respective interposer substrate 340a-d includes a respective array of interposer vias 346, as represented by the annotated checkerboard patterns. This representation is merely illustrative; there may be any suitable number, density, placement, and areal coverage of interposer vias 346. Each interposer via among interposer vias 346 may be coupled to a single lateral metal trace 342, or to multiple lateral metal traces 342 (e.g., each one of the multiple lateral metal traces connecting to a specific one of the other interposer substrates 340a-d). Those lateral metal traces may be arranged parallel to each other in a lateral plane and/or in a vertical arrangement (e.g., based on using multiple metal layers of stitched interposer 340).

On silicon layers 320a and 320b, interfaces 325a and 325b are annotated to show one implementation for connecting data flow path 300 to semiconductor package 350. Interfaces 325a and 325b may correspond to two respective silicon chips (e.g., first chip 110 and second chip 120), each of which is hybrid-bonded to a respective interposer substrate through a respective hybrid bond 330. In one illustrative data flow path, interface 325a (and the corresponding silicon chip) connects to interposer via 346a, which connects to lateral metal trace 342 (which spans a stitched region of stitched interposer 340), which connects to interposer via 346b, which connects to interface 325b (and the corresponding silicon chip).

In one implementation, a first chip (e.g., chip 110) is an application specific integrated circuit surrounded by multiple chiplets (e.g., multiple iterations of chip 120). For example, the first chip may be disposed over the center of stitched interposer 340, and there may be four chiplets disposed adjacent to the four edges of the first chip. There may be four sets of narrow data paths through stitched interposer 340, each one of the four sets connecting the first chip to a respective chiplet. The chiplets may be configured to support operation of the application specific integrated circuit, e.g., based on sharing data over the narrow data paths. The first chip may have four D2D interfaces, each of which is communicatively coupled to a respective D2D interface of one of the four chiplets through a set of narrow data paths. Moreover, each of these four respective sets of narrow data paths may span at least one stitched region 343 or 344.

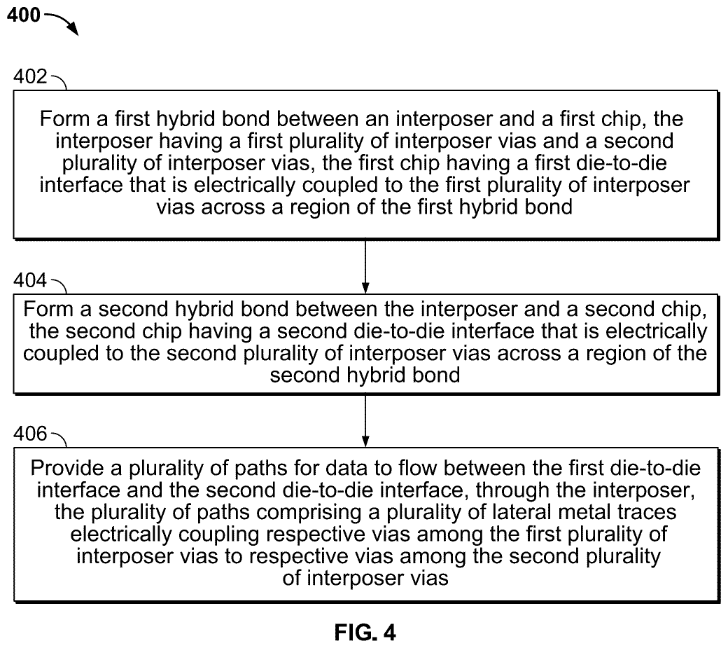

FIG. 4 is a flow diagram of an illustrative implementation of a method 400 for sharing data between die-to-die interface connections of a semiconductor package, in accordance the subject matter of this disclosure. Method 400 may include sharing data between respective chips of semiconductor package 100 (e.g., over interposer 130) or between respective chips of semiconductor package 350 (e.g., over stitched interposer 340). Method 400 may include sharing data between respective chips using a plurality of data flow paths 200 or data flow paths 300.

At 402, a first hybrid bond is formed between an interposer and a first chip, the interposer having a first plurality of interposer vias and a second plurality of interposer vias, the first chip having a first die-to-die interface that is electrically coupled to the first plurality of interposer vias across a region of the first hybrid bond.

At 404, a second hybrid bond is formed between the interposer and a second chip, the second chip having a second die-to-die interface that is electrically coupled to the second plurality of interposer vias across a region of the second hybrid bond.

At 406, a plurality of paths are provided for data to flow between the first die-to-die interface and the second die-to-die interface, through the interposer, the plurality of paths comprising a plurality of lateral metal traces electrically coupling respective vias among the first plurality of interposer vias to respective vias among the second plurality of interposer vias.

In connection with the operations at 406 and related structures that are consistent with implementations of the subject matter of this disclosure, the plurality of paths may be within a single interposer substrate (e.g., which can mean a single interposer, or which can mean a single substrate of a stitched interposer), or the plurality of paths may span at least two interposer substrates that are stitched together (i.e., such that the paths span the substrates through respective electrical connections traversing the one or more stitching region that connects the at least two substrates). Whether the plurality of paths span one interposer substrate or multiple interposer substrates, providing the plurality of paths may include driving data (e.g., using one or more buffers of the interposer) through the lateral metal traces.

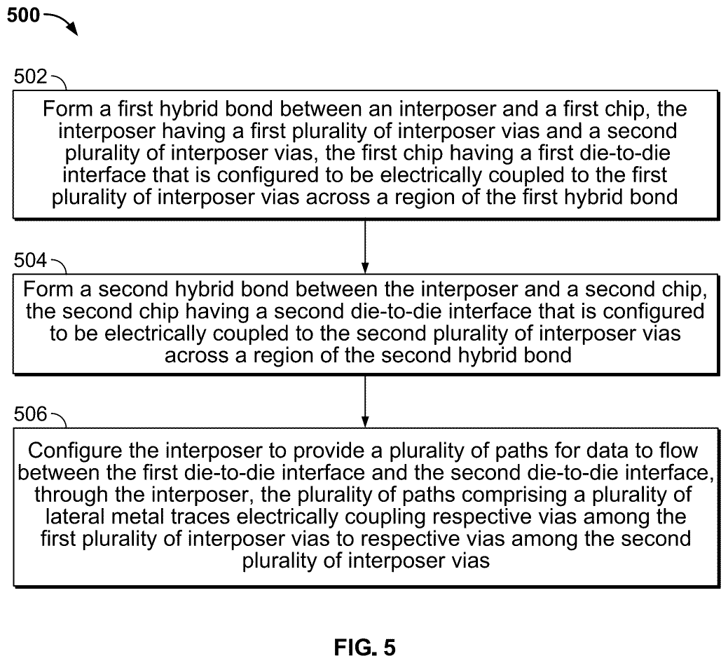

FIG. 5 is a flow diagram of an illustrative implementation of a method for manufacturing a semiconductor device, in accordance with the subject matter of this disclosure. Method 500 may include fabricating semiconductor package 100 or semiconductor package 350. Method 500 may include configuring a semiconductor package to share data between respective chips using a plurality of data flow paths 200 or data flow paths 300.

At 502, a first hybrid bond is formed between an interposer and a first chip, the interposer having a first plurality of interposer vias and a second plurality of interposer vias, the first chip having a first die-to-die interface that is configured to be electrically coupled to the first plurality of interposer vias across a region of the first hybrid bond.

At 504, a second hybrid bond is formed between the interposer and a second chip, the second chip having a second die-to-die interface that is configured to be electrically coupled to the second plurality of interposer vias across a region of the second hybrid bond.

At 506, the interposer is configured to provide a plurality of paths for data to flow between the first die-to-die interface and the second die-to-die interface, through the interposer, the plurality of paths comprising a plurality of lateral metal traces electrically coupling respective vias among the first plurality of interposer vias to respective vias among the second plurality of interposer vias.

Thus it is seen that a semiconductor package with a hybrid-bonded interposer for sharing data across the semiconductor package, a method for sharing data between high-density die-to-die interface connections of a semiconductor package, and a method of manufacturing a semiconductor package with a high density of die-to-die interface connections have been provided.

As used herein and in the claims which follow, the construction “one of A and B” shall mean “A or B.”

It is noted that the foregoing is only illustrative of the principles of the invention, and that the invention can be practiced by other than the described implementations, which are presented for purposes of illustration and not of limitation, and the present invention is limited only by the claims which follow.

What is claimed is:

1. A semiconductor package for increasing density of die-to-die interface connections, the semiconductor package comprising:
a first chip comprising a first die-to-die interface, the first die-to-die interface comprising a first plurality of flip-flops configured to send and receive data, and a second chip comprising a second die-to-die interface, the second die-to-die interface comprising a second plurality of flip-flops configured to send and receive data; and
an interposer configured to provide a plurality of paths for data to flow between the first die-to-die interface and the second die-to-die interface, the interposer being mechanically coupled to the first chip and to the second chip by a first hybrid bond and a second hybrid bond, respectively, the interposer comprising:
a first plurality of interposer vias being electrically coupled to the first plurality of flip-flops across the first hybrid bond,
a second plurality of interposer vias being electrically coupled to the second plurality of flip-flops across the second hybrid bond, and
a plurality of lateral metal traces electrically coupling respective vias among the first plurality of interposer vias to respective vias among the second plurality of interposer vias to provide the plurality of paths.

2. The semiconductor package of claim 1, wherein the interposer is configured to provide the plurality of paths for parallel data to flow at a target bandwidth between the first die-to-die interface and the second die-to-die interface.

3. The semiconductor package of claim 2, wherein the first chip and the second chip are configured to send and receive the parallel data at the target bandwidth based on respective densities of the first plurality of interposer vias and of the second plurality of interposer vias.

4. The semiconductor package of claim 1, wherein:
the first die-to-die interface further comprises a plurality of transmitters;
respective flip-flops among the first plurality of flip-flops are configured to provide respective portions of the data as parallel data; and
respective transmitters among the plurality of transmitters are configured to drive the respective portions of the data through the interposer.

5. The semiconductor package of claim 4, wherein the first die-to-die interface further comprises a plurality of buffers, respective buffers among the plurality of buffers being configured to electrically isolate a respective lateral metal trace among the plurality of lateral metal traces.

6. The semiconductor package of claim 4, wherein:
the second die-to-die interface further comprises a plurality of receivers;
respective receivers among the plurality of receivers are configured to provide the respective portions of the data to the second plurality of flip-flops; and
respective flip-flops among the second plurality of flip-flops are configured to receive the respective portions of the data.

7. The semiconductor package of claim 1, wherein the interposer comprises a plurality of buffers configured to drive the data through the plurality of paths, each buffer of the plurality of buffers being coupled to a respective path of the plurality of paths.

8. The semiconductor package of claim 1, wherein the first die-to-die interface is at least partially offset from an edge of the first chip by a distance that is greater than a maximum distance specified by Joint Electron Device Engineering Council standards.

9. The semiconductor package of claim 1, wherein the interposer comprises at least two silicon substrates stitched together, such that the interposer is larger than a maximum reticle size associated with a fabrication process used to manufacture any of the at least two silicon substrates.

10. The semiconductor package of claim 1, wherein the interposer comprises at least two silicon substrates stitched together, and each lateral metal trace among the plurality of lateral metal traces spans at least two among the at least two silicon substrates stitched together.

11. The semiconductor device of claim 1, wherein:
the first chip is an application specific integrated circuit;
the second chip is a chiplet among a plurality of chiplets configured to support operation of the application specific integrated circuit; and
the interposer is:
hybrid-bonded to each chiplet among the plurality of chiplets,
electrically coupled to each chiplet among the plurality of chiplets by a respective plurality of interposer vias and by a respective plurality of lateral metal traces, and
further configured to provide additional pluralities of paths for data to flow between the first die-to-die interface and any die-to-die interface of a respective chiplet among the plurality of chiplets.

12. A method for sharing data between die-to-die interface connections of a semiconductor package, the method comprising:
forming a first hybrid bond between an interposer and a first chip, the interposer having a first plurality of interposer vias and a second plurality of interposer vias, the first chip having a first die-to-die interface that is electrically coupled to the first plurality of interposer vias across a region of the first hybrid bond;
forming a second hybrid bond between the interposer and a second chip, the second chip having a second die-to-die interface that is electrically coupled to the second plurality of interposer vias across a region of the second hybrid bond; and
providing a plurality of paths for data to flow between the first die-to-die interface and the second die-to-die interface, through the interposer, the plurality of paths comprising a plurality of lateral metal traces electrically coupling respective vias among the first plurality of interposer vias to respective vias among the second plurality of interposer vias.

13. The method of claim 12, wherein providing the plurality of paths for data to flow comprises providing the plurality of paths for parallel data to flow at a target bandwidth between the first die-to-die interface and the second die-to-die interface.

14. The method of claim 13, further comprising configuring the first chip and the second chip to send and receive the parallel data at the target bandwidth based on respective densities of the first plurality of interposer vias and of the second plurality of interposer vias.

15. The method of claim 12, wherein the first die-to-die interface further includes a plurality of transmitters, the method further comprising:
providing respective portions of the parallel data using respective flip-flops among the first plurality of flip-flops; and
driving the respective portions of the parallel data through the interposer using respective transmitters among the plurality of transmitters.

16. The method of claim 15, wherein the first die-to-die interface further includes a plurality of buffers, the method further comprising:
electrically isolating, using the plurality of buffers, respective lateral metal traces among the plurality of lateral metal traces.

17. The method of claim 15, wherein the second die-to-die interface includes a plurality of receivers, the method further comprising:
providing, using respective receivers among the plurality of receivers, the respective portions of the parallel data to the second plurality of flip-flops; and
receiving, using respective flip-flops among the second plurality of flip-flops, the respective portions of the parallel data.

18. The method of claim 12, further comprising driving, using a plurality of buffers of the interposer, the data through the plurality of paths, each buffer of the plurality of buffers being coupled to a respective path of the plurality of paths.

19. The method of claim 12, wherein the first die-to-die interface is at least partially offset from an edge of the first chip by a distance that is greater than a maximum distance specified by Joint Electron Device Engineering Council standards.

20. The method of claim 12, further comprising stitching together at least two silicon substrates to form the interposer, such that the interposer is larger than a maximum reticle size associated with a fabrication process used to manufacture any of the at least two silicon substrates.

21. The method of claim 12, further comprising stitching together at least two silicon substrates to form the interposer; and
configuring each lateral metal trace among the plurality of lateral metal trace to span at least two silicon substrates among the at least two silicon substrates stitched together.

22. The method of claim 12, wherein the first chip is an application specific integrated circuit and the second chip is a chiplet among a plurality of chiplets configured to support operation of the application specific integrated circuit, the method further comprising:
forming a plurality of additional hybrid bonds between the interposer and a respective chiplet among the plurality of chiplets;
electrically coupling the interposer to each chiplet among the plurality of chiplets by a respective plurality of interposer vias and by a respective plurality of lateral metal traces; and
providing, using the interposer, additional pluralities of paths for data to flow between the first die-to-die interface and any die-to-die interface of a respective chiplet among the plurality of chiplets.

23. A method of manufacturing a semiconductor package, the method comprising:
forming a first hybrid bond between an interposer and a first chip, the interposer having a first plurality of interposer vias and a second plurality of interposer vias, the first chip having a first die-to-die interface that is configured to be electrically coupled to the first plurality of interposer vias across a region of the first hybrid bond;
forming a second hybrid bond between the interposer and a second chip, the second chip having a second die-to-die interface that is configured to be electrically coupled to the second plurality of interposer vias across a region of the second hybrid bond; and
configuring the interposer to provide a plurality of paths for data to flow between the first die-to-die interface and the second die-to-die interface, through the interposer, the plurality of paths comprising a plurality of lateral metal traces electrically coupling respective vias among the first plurality of interposer vias to respective vias among the second plurality of interposer vias.
